(19) United States
(12) Patent Application Publication
(10) Pub. No.: US 2014/0191248 A1
(43) Pub. Date: Jul. 10, 2014

(54) SEMICONDUCTOR DEVICE

(71) Applicants: Hidefumi Takaya, Miyoshi-shi (JP); Masaru Nagao, Yatomi-shi (JP); Narumasa Soejima, Seto-shi (JP)

(72) Inventors: Hidefumi Takaya, Miyoshi-shi (JP); Masaru Nagao, Yatomi-shi (JP); Narumasa Soejima, Seto-shi (JP)

(73) Assignee: TOYOTA JIDOSHA KABUSHIKI KAISHA, Toyota-shi (JP)

(21) Appl. No.: 14/147,048

(22) Filed: Jan. 3, 2014

(30) Foreign Application Priority Data
Jan. 9, 2013 (JP) 2013-002087

(51) Int. Cl. H01L 23/62; H01L 29/78

(52) U.S. Cl. CPC H01L 23/62; H01L 29/7827
USPC 257/77

(57) ABSTRACT

A semiconductor device includes: a semiconductor substrate that has an element region and a peripheral region that surrounds the element region; and a gate pad that is disposed in an area that is on a surface side of the semiconductor substrate. The element region is formed with an insulated gate semiconductor element that has a gate electrode. The peripheral region is formed with a first withstand voltage retaining structure that surrounds the element region and a second withstand voltage retaining structure that is located in a position on the first withstand voltage retaining structure side from an outer edge of the element region and on the element region side from a boundary of the first withstand voltage retaining structure on the element region side. The gate pad is electrically connected to the gate electrode and is disposed in an area in which the second withstand voltage retaining structure is formed.

### INCORPORATION BY REFERENCE

The disclosure of Japanese Patent Application No. 2013-002087 filed on Jan. 9, 2013 including the specification, drawings and abstract is incorporated herein by reference in its entirety.

### BACKGROUND OF THE INVENTION

1. Field of the Invention

Techniques disclosed in this specification relate to a semiconductor device.

2. Description of Related Art

Japanese Patent Application Publication No. 2011-086746 (JP 2011-086746 A) discloses a semiconductor device in which a gate pad is formed in an inactive region. In the semiconductor device, an element region and an end region are formed in an active region. The element region is formed with a plurality of linear trench gate electrodes. The end region is formed with a plurality of end trenches that surround the plural trench gate electrodes. In other words, the gate pad is disposed on the outside of the outermost end trench. A p-type floating diffusion layer is formed at a bottom of a gate trench and a bottom of the end trench. The p-type floating diffusion layer is surrounded by an n-type drift region. In the semiconductor device, a withstand voltage is retained by a p-n junction between the p-type floating diffusion layer that is formed at the bottom of the trench and the n-type drift region and also by a p-n junction between a p-type body region and the n-type drift region.

In the semiconductor device disclosed in JP 2011-086746 A, the gate pad is disposed on an outer side of a withstand voltage retaining structure that is formed in the end region. Accordingly, if a voltage that is applied to the semiconductor device is increased, a high voltage is applied to the gate pad during reverse bias, thereby causing possible damage to the gate pad.

### SUMMARY OF THE INVENTION

The present invention provides a semiconductor device that can inhibit damage to a gate pad even when a high voltage is applied to the semiconductor device.

A first aspect of the present invention relates to a semiconductor device. A semiconductor device includes: a semiconductor substrate that has an element region and a peripheral region that surrounds the element region; and a gate pad that is disposed in an area that is on a surface side of the semiconductor substrate. The element region is formed with an insulated gate semiconductor element that has a gate electrode. The peripheral region is formed with a first withstand voltage retaining structure and a second withstand voltage retaining structure. The first withstand voltage retaining structure surrounds the element region. The second withstand voltage retaining structure is formed in a position on the first withstand voltage retaining structure side from an outer edge of the element region and on the element region side from a boundary of the first withstand voltage retaining structure on the element region side. The gate pad is electrically connected to the gate electrode and is disposed in an area in which the second withstand voltage retaining structure is formed.

In general, when a reverse bias voltage is applied to the semiconductor device, an end side on a surface of the semiconductor substrate is at higher potential than an element region side. In the semiconductor device that is disclosed in this specification, the first withstand voltage retaining structure is formed on an outer side of the gate pad (that is, an end side of the semiconductor substrate). Accordingly, even if the high reverse bias voltage is applied to the semiconductor device, an electric field is reduced by the first withstand voltage retaining structure. Meanwhile, the second withstand voltage retaining structure is formed between the element region and the first withstand voltage retaining structure. Accordingly, the second withstand voltage retaining structure inhibits the withstand voltage from being lowered between the element region and the first withstand voltage retaining structure. Therefore, even when the high reverse bias voltage is applied to the semiconductor device, it is possible to inhibit damage to the gate pad that is disposed in the area on the surface side of the semiconductor substrate and in which the second withstand voltage retaining structure is formed.

The details of techniques that are disclosed in this specification and improvements thereof will be described in detail in the detailed description of embodiments and examples.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a plan view of a semiconductor device of an example 1 according to an embodiment of the present invention;

FIG. 2 is a vertical cross-sectional view taken along the line II-II of FIG. 1;

FIG. 3 is a plan view of a semiconductor device according to a related art;

FIG. 4 is a vertical cross-sectional view taken along the line IV-IV of FIG. 3;

FIG. 5 is a plan view of a semiconductor device of a modified example 1 according to the embodiment of the present invention;

FIG. 6 is a vertical cross-sectional view taken along the line VI-VI of FIG. 5;

FIG. 7 is a plan view of a semiconductor device of a modified example 2 according to the embodiment of the present invention;

FIG. 8 is a vertical cross-sectional view taken along the line VIII-VIII of FIG. 7;

FIG. 9 is a plan view of a semiconductor device of a modified example 3 according to the embodiment of the present invention;

FIG. 10 is a vertical cross-sectional view taken along the line X-X of FIG. 9; and

FIG. 11 is a vertical cross-sectional view of a semiconductor device of a modified example 4 according to the embodiment of the present invention.

### DETAILED DESCRIPTION OF EMBODIMENTS

Principle structures of examples that will be described below are listed. It should be noted that technical elements described below are independent from each other and thus demonstrate technical utility when used singly or in various combinations.

### Structure 1

In a semiconductor device disclosed in this specification, a first withstand voltage retaining structure may have at least one end trench that extends from a surface of a semiconductor substrate in a depth direction. According to the structure 1, when a high reverse bias voltage is applied to the semiconductor device, an electric field is reduced by the end trench that is included in the first withstand voltage retaining structure, and thus a voltage that is applied to a gate pad is lowered. Therefore, it is possible with this structure to appropriately retain the withstand voltage.

### Structure 2

In the semiconductor device disclosed in this specification, an element region may be formed with a body region of a first conductive type, a drift region of a second conductive type, a gate electrode, an insulator, and a floating region of a first conductive type. The body region of the first conductive type may be disposed in an area that faces an upper surface of the semiconductor substrate. The drift region of the second conductive type may be in contact with a lower surface of the body region. The gate electrode may be disposed in a gate trench that penetrates the body region and extends to the drift region, and may face the body region. The insulator may be disposed between the gate electrode and an inner wall of the gate trench. The floating region of the first conductive type may surround a bottom of the gate trench and may be surrounded by the drift region. According to the structure 2, when the reverse bias voltage is applied to the semiconductor device, the withstand voltage is retained in two positions that are the body region of the first conductive type and the floating region of the first conductive type. Therefore, it is possible with this structure to appropriately retain the withstand voltage even when the high reverse bias voltage is applied to the semiconductor device.

### Structure 3

In the semiconductor device disclosed in this specification, the body region of the first conductive type and the drift region of the second conductive type may be formed in a peripheral region. The first withstand voltage retaining structure may be the end trench that penetrates the body region from a surface of the semiconductor substrate and extends to the drift region. The end trench may have the floating region of the first conductive type that surrounds the bottom of the at least one end trench and that is surrounded by the drift region. According to the structure 3, when the reverse bias voltage is applied to the semiconductor device, the withstand voltage is retained in the two positions that are the body region of the first conductive type and the floating region of the first conductive type in the end trench that is formed with the floating region of the first conductive type. In the end trench that is not formed with the floating region of the first conductive type, the withstand voltage is retained in the body region of the first conductive type. Thus, it is possible with this structure to appropriately retain the withstand voltage, and the electric field is reduced by the end trench that is disposed on the outer side of the gate pad. Therefore, it is possible to lower a voltage that is applied to the gate pad.

### Structure 4

In the semiconductor device disclosed in this specification, a second withstand voltage retaining structure may be a trench that penetrates the body region from the surface of the semiconductor substrate and extends to the drift region. The trench may have the floating region of the first conductive type that surrounds a bottom of the trench and is surrounded by the drift region. According to the structure 4, when the reverse bias voltage is applied to the semiconductor device, the withstand voltage is retained in the two positions that are the body region of the first conductive type and the floating region of the first conductive type. Therefore, it is possible with the second withstand voltage retaining structure to inhibit the withstand voltage from being lowered and to inhibit damage to the gate pad.

### Structure 5

In the semiconductor device disclosed in this specification, the second withstand voltage retaining structure may have the floating region of the first conductive type that is formed in the drift region. According to the structure 5, when the reverse bias voltage is applied to the semiconductor device, the withstand voltage is retained in the two positions that are the body region of the first conductive type and the floating region of the first conductive type. Therefore, it is possible with the second withstand voltage retaining structure to inhibit the withstand voltage from being lowered and to inhibit damage to the gate pad.

### Structure 6

The semiconductor device disclosed in this specification may include the semiconductor substrate made of SiC. In general, the semiconductor substrate made of SiC is commonly used in a high voltage environment. Therefore, it is possible with the semiconductor device disclosed in this specification to appropriately retain the withstand voltage in the environment where the high reverse bias voltage is applied thereto.

### Example 1

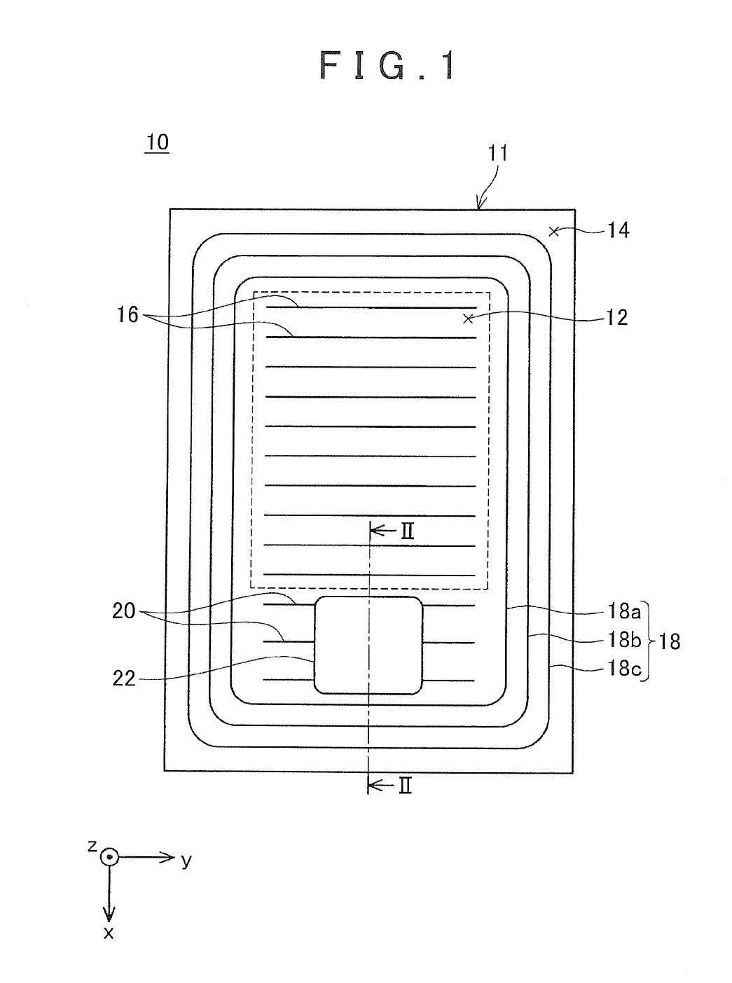

A description will hereinafter be made on a semiconductor device 10 of the example 1 according to an embodiment of the present invention with reference to the drawings. As shown in FIG. 1, the semiconductor device 10 is formed in a semiconductor substrate 11. The semiconductor substrate 11 is formed with an element region 12 and a peripheral region 14 that surrounds the element region 12. A known semiconductor substrate (such as a Si substrate or a SiC substrate, for example) can be used as the semiconductor substrate 11.

A plurality of gate electrodes 16 are formed in the element region 12. The plural gate electrodes 16 extend in a y-direction of FIG. 1 and are arranged at certain intervals in an x-direction of FIG. 1. The peripheral region 14 is formed with three end trenches 18 (18a to 18c) and three trenches 20. Each of the end trenches 18 makes one round of the element region 12. The trenches 20 are formed in a position on the end trenches 18 side from an outer edge of the element region 12 and on the element region 12 side from the innermost end trench 18a of the end trenches 18. Similar to the gate electrodes 16, the trenches 20 extend in the y-direction of FIG. 1 and are arranged at certain intervals in the x-direction of FIG. 1. A gate pad 22 is disposed above the trenches 20, that is, in an area in an upper surface of the semiconductor substrate 11 where the trenches 20 are formed, via an insulation film 44, which will be described below. A detailed description will be made on the gate pad 22 below. It should be noted that the end trench 18 corresponds to an example of “the first withstand voltage retaining structure” and that the trench 20 corresponds to an example of “the second withstand voltage retaining structure”.

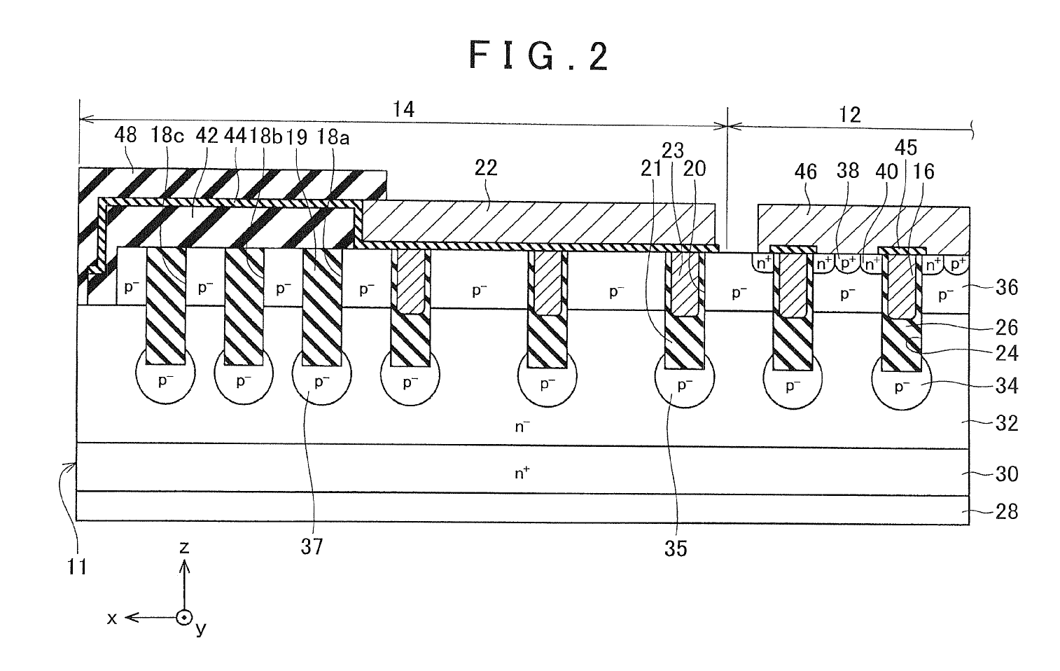

A structure of the element region 12 will now be described. As shown in FIG. 2, an insulated gate semiconductor element is formed in the element region 12. More specifically, an n+ source region 40 and a p+ body contact region 38 are formed in a region in the element region 12 that faces the upper surface of the semiconductor substrate 11. The body contact region 38 is formed to contact the source region 40.

A p− body region 36 is formed on a lower side of the source region 40 and the body contact region 38. The impurity concentration of the body region 36 is set to be lower than the impurity concentration of the body contact region 38. The body region 36 is in contact with the source region 40 and the body contact region 38. Thus, the source region 40 is surrounded by the body region 36 and the body contact region 38. The body region 36 is formed up to the outer side of the end trench 18c that is located on the outermost periphery of the peripheral region 14. It should be noted that the p− body region 36 corresponds to an example of “the body region of the first conductive type”.

An n− drift region 32 is formed on a lower side of the body region 36. The drift region 32 is formed over the entire surface of the semiconductor substrate 11. The drift region 32 is in contact with a lower surface of the body region 36. The drift region 32 is separated from the source region 40 by the body region 36. A p− diffusion region 34 is formed in an area of the drift region 32 that surrounds a bottom of a gate trench 24, which will be described later. The diffusion region 34 is in contact with an insulator 26 that is located below the gate electrode 16 (that is, at the bottom of the gate trench 24). The diffusion region 34 is surrounded by the drift region 32. Accordingly, the diffusion region 34 is separated from the body region 36. It should be noted that the n− drift region 32 corresponds to an example of “the drift region of the second conductive type” and that the p− diffusion region 34 corresponds to an example of “the floating region of the first conductive type”.

An n+ drain region 30 is formed in an area that faces a lower surface of the semiconductor substrate 11. The drain region 30 is formed over the entire surface of the semiconductor substrate 11. The impurity concentration of the drain region 30 is set to be higher than the impurity concentration of the drift region 32. The drain region 30 is in contact with a lower surface of the drift region 32. The drain region 30 is separated from the body region 36 by the drift region 32.

The gate trench 24 is formed in the upper surface of the semiconductor substrate 11. The gate trench 24 penetrates the source region 40 and the body region 36, and a lower end thereof extends to the drift region 32. The gate electrode 16 is formed in the gate trench 24. The gate electrode 16 is formed such that a lower end thereof is slightly deeper than the lower surface of the body region 36. A space between a wall surface of the gate trench 24 and the gate electrode 16 (that is, on a side and below the gate electrode 16) is filled with the insulator 26. Accordingly, the gate electrode 16 faces the body region 36 and the source region 40 via the insulator 26. A cap insulation film 45 is formed on an upper surface of the gate electrode 16. Although the gate electrode 16 is made of polysilicon, for example, it may be made of another substance.

A drain electrode 28 is formed on the lower surface of the semiconductor substrate 11. The drain electrode 28 is formed over the entire surface of the semiconductor substrate 11. The drain electrode 28 is in ohmic contact with the drain region 30. A source electrode 46 is formed on the upper surface of the semiconductor substrate 11. The source electrode 46 is formed in the element region 12. The source electrode 46 is in ohmic contact with the source region 40 and the body contact region 38. The source electrode 46 is insulated from the gate electrode 16 by the cap insulation film 45.

Next, the peripheral region 14 will be described. As shown in FIG. 2, the three end trenches 18 (18a to 18c) and the three trenches 20 are formed in the peripheral region 14. The p− body region 36 and the n− drift region 32 that is in contact with the lower surface of the body region 36 are also formed in an area of the peripheral region 14 that faces the upper surface of the semiconductor substrate 11. The end trench 18 penetrates the body region 36, and a lower end thereof extends to the drift region 32. The lower end of the end trench 18 is at the same depth as the lower end of the gate trench 24. The end trench 18 is filled with an insulator 19. A p− diffusion region 37 is formed in an area that surrounds the bottom of the end trench 18. The diffusion region 37 is surrounded by the drift region 32. Meanwhile, the trench 20 also penetrates the body region 36, and a lower end thereof is at the same depth as that of the end trench 18. A polysilicon region 23 is formed in the trench 20. The polysilicon region 23 is formed such that a lower end thereof is slightly deeper than the lower surface of the body region 36. A space between a wall surface of the trench 20 and the polysilicon region 23 (that is, on a side and below the polysilicon region 23) is filled with an insulator 21. Accordingly, the polysilicon region 23 faces the body region 36 via the insulator 21. A p− diffusion region 35 that is surrounded by the drift region 32 is formed at the bottom of the trench 20. In other words, the structure of the trench 20 is the same as the structure of the gate trench 24. The polysilicon region 23 is electrically connected to the gate pad 22 in a region not shown in FIG. 2. It should be noted that the intervals of the trenches 20 are not necessarily the same as the intervals of the gate trenches 24. It should also be noted that the p− diffusion regions 37, 35 correspond to an example of “the floating region of the first conductive type”.

On the upper surface of the semiconductor substrate 11 in the peripheral region 14, an insulation layer 42 is formed to cover the end trenches 18. The insulation layer 42 covers an end (a side surface) of the body region 36. Thus, the end of the body region 36 is not exposed. On an upper surface of the insulation layer 42, the insulation film 44 is formed to cover an upper surface of the insulation layer 42 and upper surfaces of the trenches 20. More specifically, the insulation film 44 covers the upper surface of the insulation layer 42, a part of a side surface of the insulation layer 42, and a part of the upper surface of the semiconductor substrate 11. The gate pad 22 is disposed on an upper surface of the insulation film 44 and above the trenches 20. In other words, the gate pad 22 is disposed between an outer edge of the element region 12 and the innermost end trench 18a of the end trenches 18 (that is, the end trench on the element region side among the end trenches 18). As shown in FIG. 1, the gate pad 22 is in a rectangular shape and is disposed substantially at the center of the semiconductor substrate 11 in the y-direction. The gate pad 22 is electrically connected to the gate electrode 16 by gate wiring (not shown). The gate wiring is connected to both ends of the each gate electrode 16 in a longitudinal direction thereof, for example. As long as the gate pad 22 is formed on the insulation film 44 and the gate electrode 16 at the opening of the cap insulation film 45 and the gate pad 22 are connected by the gate wiring, the arrangement of the gate wiring on the insulation film is not limited. For example, a part of the gate wiring between the gate electrode 16 on the element region 12 and the gate pad 22 may be provided outside the annular end trench 18. The entire gate wiring may be provided inside the annular end trench 18. One end of a wire (not shown) is bonded to the gate pad 22, and the gate pad 22 is connected to an external circuit by the wire. The body region 36 that is below the gate pad 22 and the body region 36 that is below aluminum wiring (not shown) are at the same potential as the source electrode 46.

As shown in FIG. 1, a space in the x-direction between the gate electrode 16 that is located at one end in the x-direction (strictly, the gate trench 24 that has the gate electrode 16) and the end trench 18a and a space in the x-direction between the gate electrode 16 that is located at another end in the x-direction and the trench 20 that is adjacent to this gate electrode 16 are substantially the same as the interval of the gate trenches 24 in the x-direction. In addition, a space between the gate electrode 16 that is adjacent to the gate pad 22 and one side of the end trench 18a that is adjacent to the gate pad 22 is slightly larger than a length of the gate pad 22 in the x-direction. Furthermore, a space between the end trench 18a and the trench 20 that is adjacent to the end trench 18a is substantially the same as the interval of the end trenches 18.

As shown in FIG. 2, an insulation layer 48 is formed on the semiconductor substrate 11 to cover a part of the insulation film 44 and a part of the gate pad 22. The insulation layer 48 covers the end of the insulation layer 42 and the end of the insulation film 44.

When the above-mentioned semiconductor device 10 is used, the drain electrode 28 is connected to power supply potential, and the source electrode 46 is connected to ground potential. If the potential that is applied to the gate pad 22 is lower than threshold potential, the semiconductor device 10 remains off. When the semiconductor device 10 is off, a depletion layer expands by a p-n junction at an interface between the body region 36 and the drift region 32 and by a p-n junction at an interface between the drift region 32 and each of the diffusion regions 34, 35, 37.

When the potential that is applied to the gate pad 22 becomes equal to or larger than the threshold potential, the semiconductor device 10 is turned on. In other words, in the element region 12, the potential that is applied to the gate pad 22 is applied to both ends of the gate electrode 16 through the gate wiring. When the potential that is applied to the gate electrode 16 becomes equal to or larger than the threshold potential, a channel is formed in an area of the body region 36 that is in contact with the insulator 26. Accordingly, electrons travel from the source electrode 46 to the drain electrode 28 through the source region 40, the channel in the body region 36, the drift region 32, and the drain region 30. That is, current flows from the drain electrode 28 to the source electrode 46.

Next, a description will be made on advantages of the semiconductor device 10 of the example 1 with reference to FIGS. 1 to 4 and a semiconductor device according to a related art as a comparative example. It should be noted that same components as those in the semiconductor device 10 of the example 1 are denoted by the same reference numerals and detailed descriptions thereof will not be repeated.

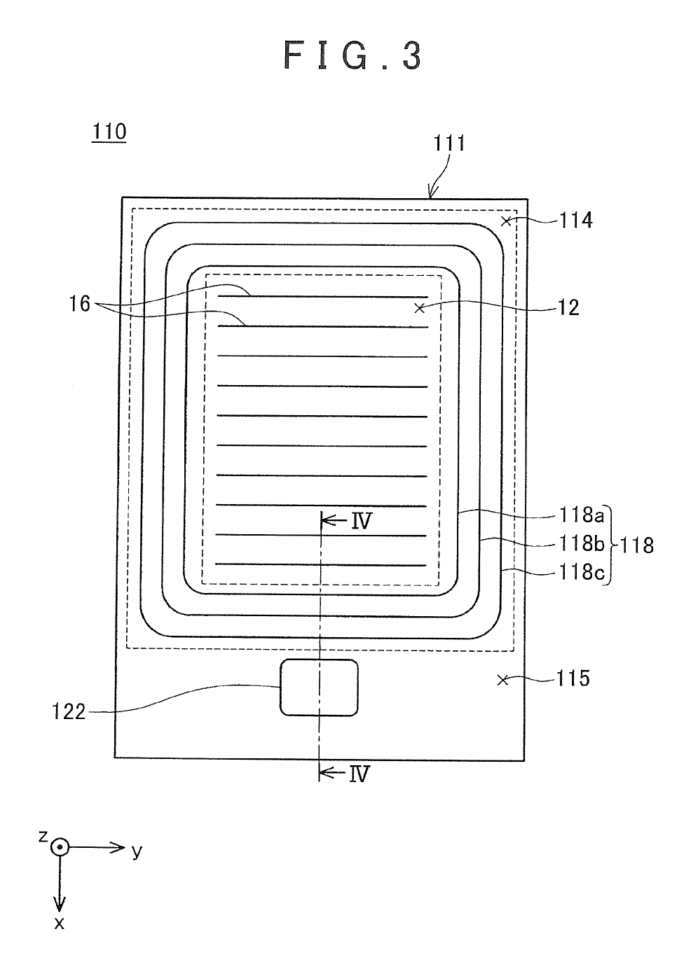

FIG. 3 is a plan view of a semiconductor device 110 according to a related art. As shown in FIG. 3, in the semiconductor device 110 according to the related art, a semiconductor substrate 111 is provided with the element region 12, a first peripheral region 114, and a second peripheral region 115. Three end trenches (118a to 118c) are formed in the first peripheral region 114. A gate pad 122 is disposed in the second peripheral region 115.

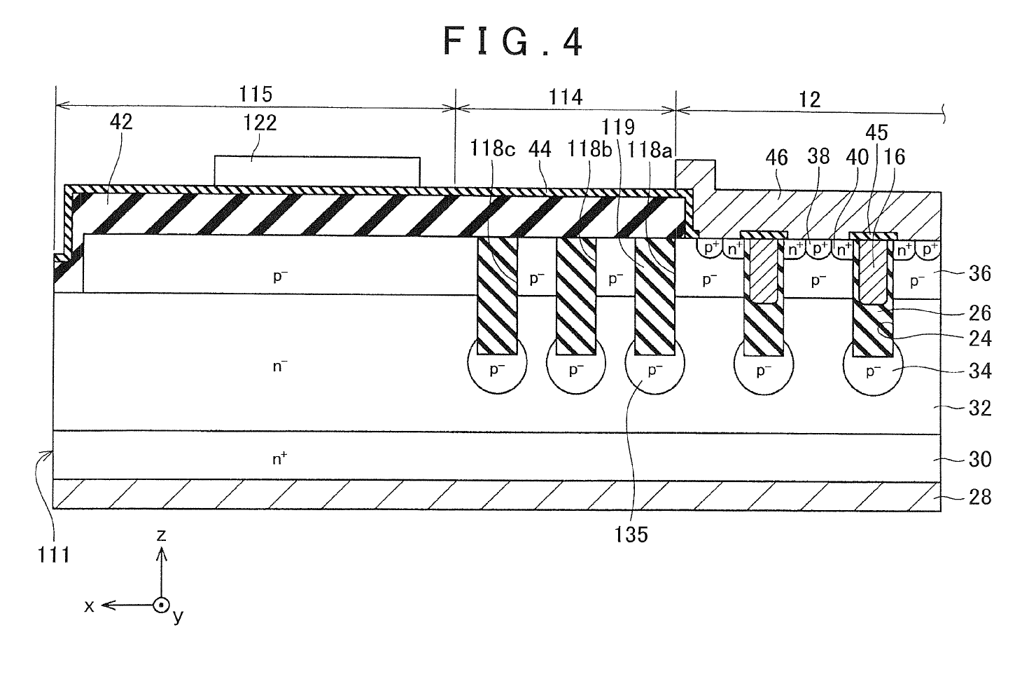

As shown in FIG. 4, the end trench 118 penetrates the body region 36, and a lower end thereof extends to the drift region 32. The lower end of the end trench 118 is at the same depth as the lower end of the gate trench 24. The end trench 118 is filled with an insulator 119. A p− diffusion region 135 is formed in an area that surrounds a bottom of the end trench 118. The diffusion region 135 is surrounded by the drift region 32. In other words, the end trench 118 of the semiconductor device 110 according to the related art has the same structure as the end trench 18 of the example 1.

As shown in FIGS. 3 and 4, in the semiconductor device 110 according to the related art, the gate pad 122 is disposed on an outer side of the end trenches 118 (that is, an end side of the semiconductor substrate 111). In general, when a voltage in a reverse bias direction is applied to a semiconductor device, an end side of a semiconductor substrate obtains high potential. If the semiconductor substrate 111 is a SiC substrate, for example, the high reverse bias voltage is applied to the semiconductor device 110 (such as 1200 V). In this case, the end of the semiconductor substrate 111 receives the high potential, and accordingly, the insulation layer 42 and the insulation film 44 that are formed between the gate pad 122 and the semiconductor substrate 111 are destroyed. As a result, the gate pad 122 is possibly damaged.

On the other hand, as shown in FIGS. 1 and 2, the end trenches 18 are formed on the outer side of the gate pad 22 in the semiconductor device 10 of this example. Thus, even when the high reverse bias voltage of 1200 V is applied to the semiconductor device 10, for example, the electric field is reduced by the end trenches 18, and thus the voltage that is applied to the gate pad 22 is lowered. In addition, because of the formation of the gate pad 22, the element region 12 is separated from the end trench 18a. The trenches 20 are formed between the element region 12 and the end trench 18a. Thus, the trenches 20 can inhibit the withstand voltage from being lowered between the element region 12 and the end trench 18a. Therefore, even when the high reverse bias voltage is applied to the semiconductor device 10, it is possible to inhibit damage to the gate pad 22 that is formed above the trenches 20.

In addition, as shown in FIG. 2, in the semiconductor device 10 of this example, the body region 36 that extends to the outer side of the end trench 18c is formed in the peripheral region 14, and the diffusion region 37 is formed at the bottom of the end trench 18. Accordingly, when the high reverse bias voltage is applied to the semiconductor device 10, the depletion layer expands by the two p-n junctions (that are the p-n junction at the interface between the body region 36 and the drift region 32 and the p-n junction at the interface between the diffusion region 37 and the drift region 32) in the vicinity of the end trenches 18. Because the depletion layer is formed in a wide area near the end trenches 18, the withstand voltage at the end of the semiconductor substrate is retained, and the electric field can be reduced. The diffusion region 35 is also formed at the bottom of the trench 20. Like the gate trench 24, the polysilicon region 23 is formed in the trench 20. The polysilicon region 23 is electrically connected to the gate pad 22. Thus, the polysilicon region 23 is at the same potential as the gate electrode 16. Therefore, the trench 20 in the peripheral region 14 exhibits a same withstand voltage retaining effect as the gate trench 24 in the element region 12.

In other words, even when the high reverse bias voltage is applied to the semiconductor device 10, the withstand voltage in a vertical direction (a z-direction of FIG. 2) and a width direction (an x-y plane of FIG. 2) of the semiconductor device 10 near the trenches 20 can be retained without being lowered by the two p-n junctions (that are the p-n junction at the interface between the body region 36 and the drift region 32 and the p-n junction at the interface between the diffusion region 35 and the drift region 32) and by the polysilicon region 23. Furthermore, as described above, the space between the end trench 18a and the trench 20 that is adjacent to the end trench 18a is substantially the same as the interval of the end trenches 18. The space between the gate trench 24 that is adjacent to the gate pad 22 and the trench 20 that is adjacent to this gate trench 24 is substantially the same as the interval of the gate trenches 24 in the x-direction. Accordingly, even when the high reverse bias voltage is applied to the semiconductor device 10, the withstand voltage in the width direction (the x-y plane of FIG. 2) of the semiconductor device 10 can be retained without being lowered. As a result, it is possible to inhibit damage to the gate pad 22. Moreover, because the end trenches 18 are formed on the outer side of the gate pad 22, an area on an inner side of the end trench 18a can be increased when compared to that in the semiconductor device 110 according to the related art. Thus, when the high reverse bias voltage is applied to the semiconductor device 10, the withstand voltage can be retained in the large area. This allows an improvement in avalanche resistance.

### Modified Example 1

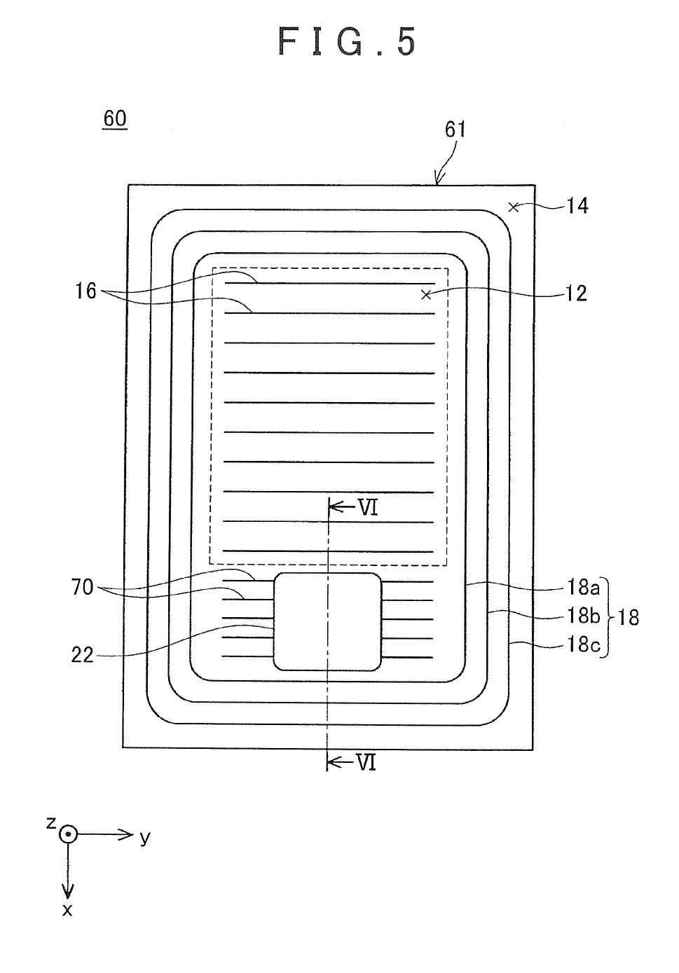

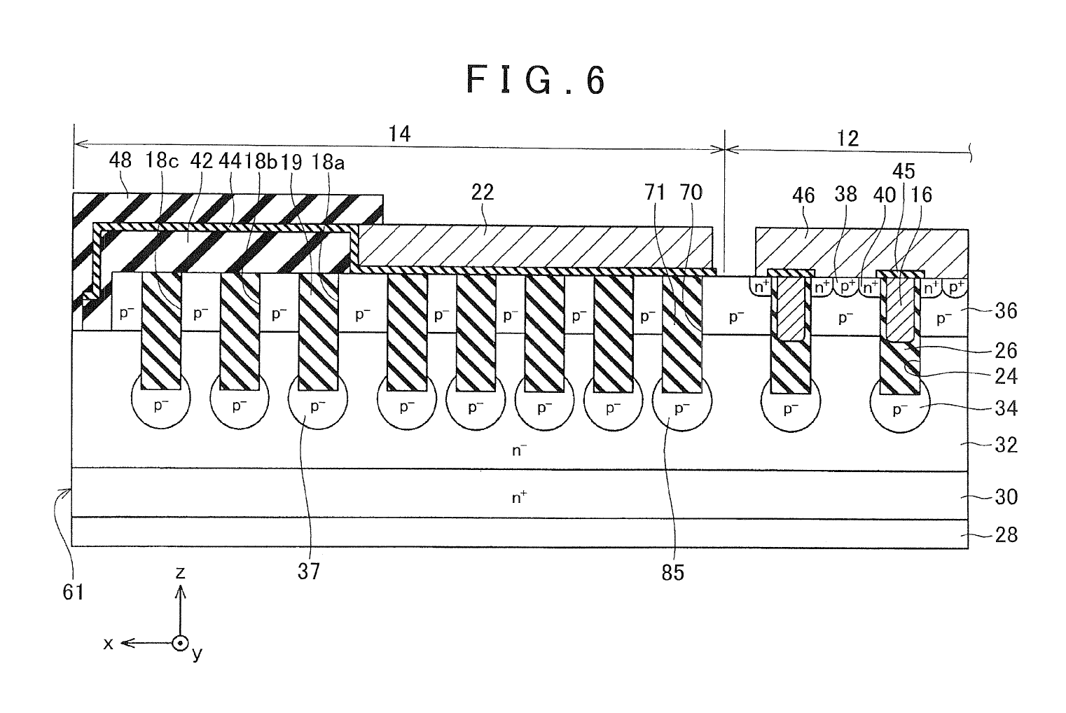

Next, a description will be made on a modified example 1 of the example 1 with reference to FIGS. 5 and 6. A description will hereinafter be made only on differences from the example 1, and a detailed description of the same structure as the example 1 will not be repeated.

As shown in FIG. 5, in a semiconductor device 60 of the modified example 1, an interval between adjacent trenches 70 is smaller than the interval between the adjacent trenches 20 in the example 1. An area in which the trenches 70 are formed is in the same size as that in the example 1. Accordingly, due to the smaller intervals, the number of the trench 70 is larger than that in the example 1. As shown in FIG. 6, although the trench 70 is filled with an insulator 71, the trench 70 is not formed with a polysilicon region. The same advantages as the semiconductor device 10 of the example 1 can be obtained by such a structure. More specifically, the polysilicon region is not formed in the trench 70 of the semiconductor device 60. Thus, when the reverse bias voltage is applied to the semiconductor device 60, an area in which the depletion layer expands in the vicinity of the trench 70 is smaller than that in the semiconductor device 10 of the example 1. Accordingly, the withstand voltage in the width direction (the x-y plane of FIG. 6) of the semiconductor device 60 can be retained without being lowered by disposing the trenches 70 more tightly than the trenches 20, and thus it is possible to inhibit damage to the gate pad 22. Furthermore, because the polysilicon region is not formed in the trench 70, the trench 70 has excellent durability against damage during wire bonding, and this allows improvement in fracture strength of the semiconductor device 60. It should be noted that the withstand voltage in the vertical direction (the z-direction) of the semiconductor device 60 can also be retained appropriately by widening the trench 70 in the x-direction or by deepening the trench 70 in a z-direction. It should also be noted that a diffusion region 85 in FIG. 6 corresponds to an example of “the floating region of the first conductive type”.

### Modified Example 2

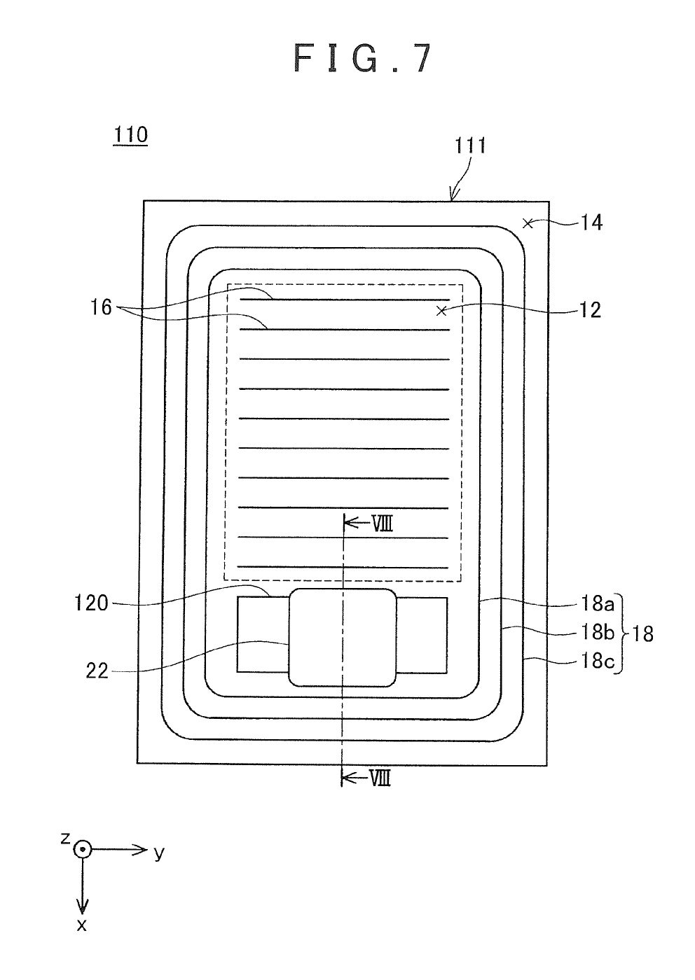

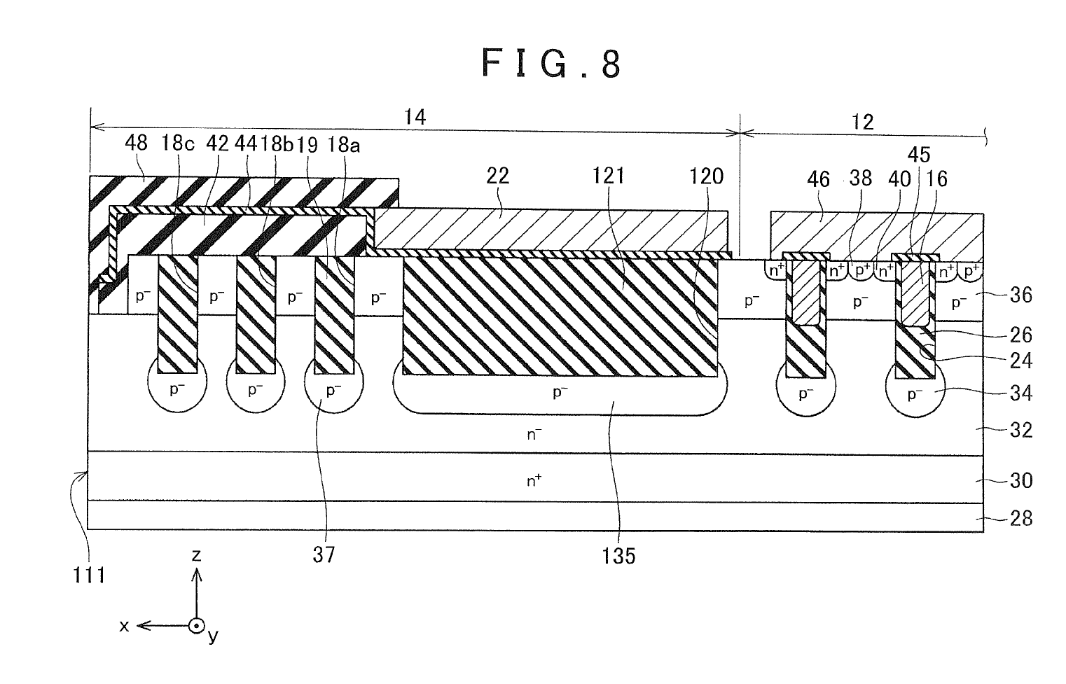

Next, a description will be made on a modified example 2 of the example 1 with reference to FIGS. 7 and 8. A description will hereinafter be made only on differences from the example 1, and a detailed description of the same structure as the example 1 will not be repeated.

As shown in FIG. 7, one trench 120 is formed in the semiconductor device 110 of the modified example 2. The trench 120 is wider than the trench 20 in the x-direction. In addition, as shown in FIG. 8, the trench 120 is filled with an insulator 121 and is not formed with a polysilicon region. The diffusion region 135 that is wide in the x-direction is formed at a bottom of the trench 120. The same advantages as the semiconductor device 10 of the example 1 can be obtained by such a structure. It should be noted that the diffusion region 135 corresponds to an example of “the floating region of the first conductive type”.

### Modified Example 3

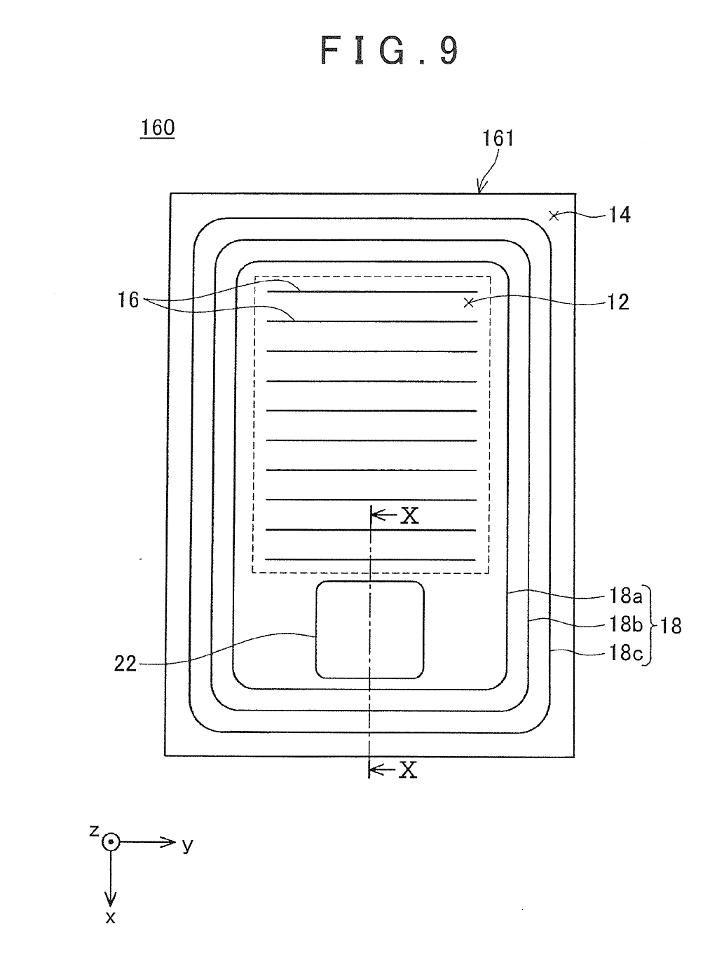

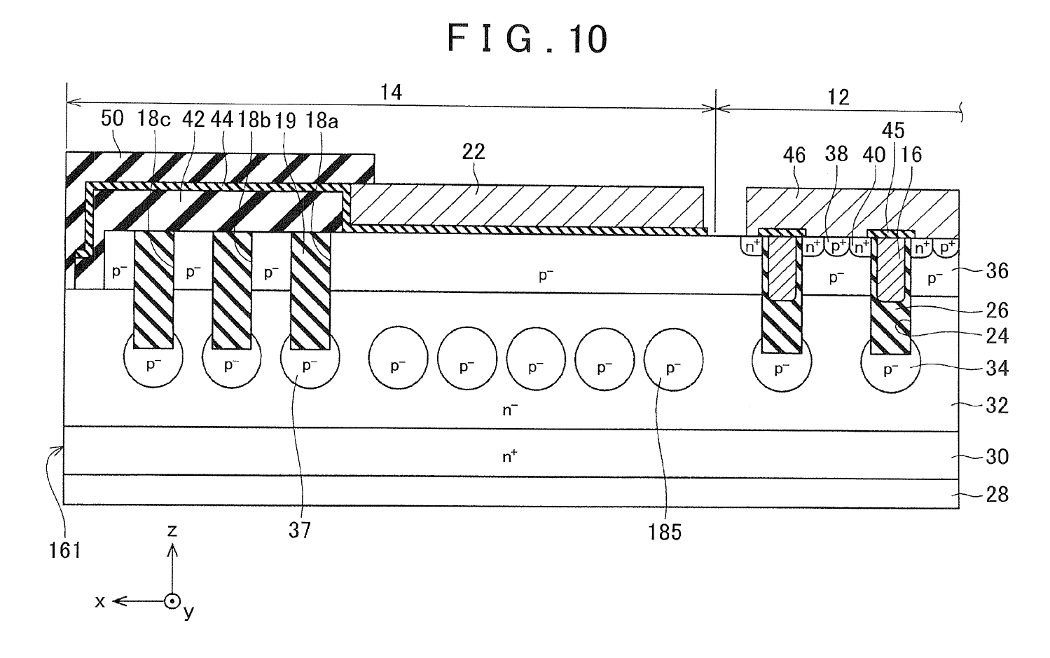

Next, a description will be made on a modified example 3 of the example 1 with reference to FIGS. 9 and 10. A description will hereinafter be made only on differences from the example 1, and a detailed description of the same structure as the example 1 will not be repeated.

As shown in FIGS. 9 and 10, a trench is not formed in a semiconductor device 160 of the modified example 3, and plural diffusion regions 185 are formed in the drift region 32. Each of the diffusion regions 185 is formed to have substantially the same depth as the diffusion regions 34, 37 and substantially the same size as the diffusion regions 34, 37, and the diffusion regions 185 are disposed substantially at equal intervals. The gate pad 22 is disposed on a surface side of a semiconductor substrate 161 and above the diffusion regions 185. The same advantages as the semiconductor device 10 of the example 1 can be obtained by such a structure. It should be noted that the diffusion region 185 corresponds to an example of “the floating region of the first conductive type”.

### Modified Example 4

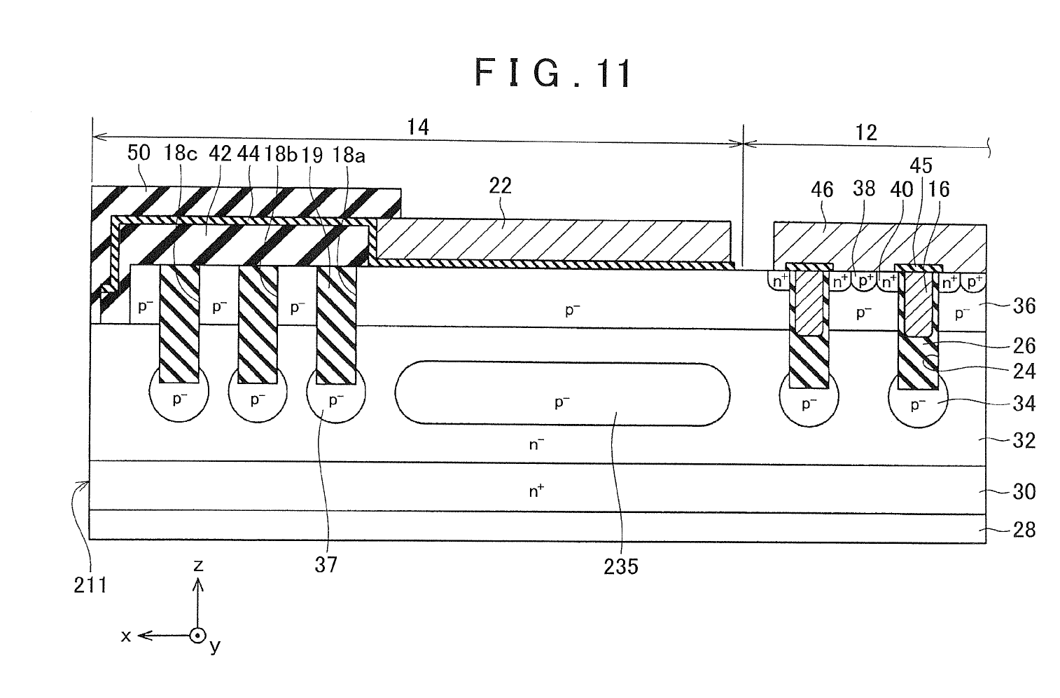

Next, a description will be made on a modified example 4 of the example 1 with reference to FIG. 11. A description will hereinafter be made only on differences from the example 1, and a detailed description of the same structure as the example 1 will not be repeated.

As shown in FIG. 11, a trench is not formed in a semiconductor device of the modified example 4, and a diffusion region 235 that is wide in the x-direction is formed in the drift region 32. The diffusion region 235 is formed to have substantially the same depth as the diffusion regions 34, 37. The gate pad 22 is formed on a surface side of a semiconductor substrate 211 and above the diffusion region 235. The same advantages as the semiconductor device 10 of the example 1 can be obtained by such a structure. It should be noted that the diffusion region 235 corresponds to an example of “the floating region of the first conductive type”.

The examples of the techniques disclosed in this specification have been described so far in detail; however, they are merely illustrative. Various modifications of and changes to the above examples are included in a semiconductor device and a manufacturing method of a semiconductor device that are disclosed in this specification.

For example, each of the withstand voltage retaining structures is not limited to a structure using a trench and may be a field limiting ring (FLR) structure or another withstand voltage retaining structure. In addition, an element structure formed in the element region 12 is not limited to MOS but may be a switching element such as IGBT or a diode. Furthermore, there is no need to form the diffusion region 37 at the bottoms of all the end trenches 18 as long as the withstand voltage can be retained. Moreover, the gate pad 22 may be disposed in a position other than the substantial center in the y-direction of FIG. 1. It should be noted that the “p-type” corresponds to the “second conductive type” when the “n-type” corresponds to the “first conductive type”. The polysilicon region 23 that is formed in the trench 20 of the example 1 may be made of a conductive material other than polysilicon. In addition, the number of the end trench 18 is not limited to the number that is raised in the above example and modified examples. Furthermore, the diffusion regions 185 of the modified example 3 and the diffusion region 235 of the modified example 4 are formed by ion implantation or by an embedded epitaxial method, for example. However, the diffusion regions 185 and the diffusion region 235 may be formed by another method. Moreover, the gate pad 22 may not be electrically connected to the polysilicon region 23 in the trench 20. In other words, the polysilicon region 23 may have floating potential.

The illustrative examples of the present invention have been described so far in detail; however, they are merely illustrative and thus do not limit the scope of the claims. Techniques that are described in the claims include various modifications of and changes to the above illustrative examples. In addition, technical elements that are described in this specification and the drawings demonstrate technical utility when used singly or in various combinations. The techniques that are illustrated in this specification and the drawings simultaneously achieve plural purposes and demonstrate technical utility by achieving one of the purposes.

What is claimed is:

1. A semiconductor device comprising:
a semiconductor substrate that has an element region and a peripheral region that surrounds the element region; and
a gate pad that is disposed in an area that is on a surface side of the semiconductor substrate, wherein
an insulated gate semiconductor element that has a gate electrode is formed in the element region,
the peripheral region is formed with a first withstand voltage retaining structure that surrounds the element region and a second withstand voltage retaining structure that is located in a position on the first withstand voltage retaining structure side from an outer edge of the element region and on the element region side from a boundary of the first withstand voltage retaining structure on the element region side, and
the gate pad is electrically connected to the gate electrode and is disposed in an area in which the second withstand voltage retaining structure is formed.

2. The semiconductor device according to claim 1,
wherein the first withstand voltage retaining structure has at least one end trench that extends from a surface of the semiconductor substrate in a depth direction.

3. The semiconductor device according to claim 2,
wherein the element region is formed with: a body region of a first conductive type that is disposed in an area that faces an upper surface of the semiconductor substrate; a drift region of a second conductive type that is in contact with a lower surface of the body region; the gate electrode disposed in a gate trench that penetrates the body region and extends to the drift region and facing the body region; an insulator that is disposed between the gate electrode and an inner wall of the gate trench; and a floating region of a first conductive type that surrounds a bottom of the gate trench and is surrounded by the drift region.

4. The semiconductor device according to claim 3, wherein
the peripheral region is formed with the body region of the first conductive type that is disposed in the area facing the upper surface of the semiconductor substrate and the drift region of the second conductive type that faces the lower surface of the body region,
the first withstand voltage retaining structure is the end trench that penetrates the body region from the surface of the semiconductor device and extends to the drift region, and
the end trench has the floating region of the first conductive type that surrounds a bottom of the at least one end trenches and is surrounded by the drift region.

5. The semiconductor device according to claim 4, wherein
the second withstand voltage retaining structure is the trench that penetrates the body region from the surface of the semiconductor substrate and extends to the drift region, and
the trench has the floating region of the first conductive type that surrounds a bottom of the trench and is surrounded by the drift region.

6. The semiconductor device according to claim 4,
wherein the second withstand voltage retaining structure has the floating region of the first conductive type that is formed in the drift region.

7. The semiconductor device according to claim 1,
wherein the semiconductor substrate is made of SiC.
